(19) United States
(12) Patent Application Publication
(10) Pub. No.: US 2026/0323872 A1
(43) Pub. Date: Oct. 15, 2026

(54) POWER MODULE COOLER

(71) Applicants: Hyundai Motor Company, Seoul (KR); Kia Corporation, Seoul (KR); KOREA ADVANCED INSTITUTE OF SCIENCE AND TECHNOLOGY, Daejeon (KR)

(72) Inventors: Su Hyeon MAENG, Hwaseong-si (KR); Kwang Min CHOI, Hwaseong-si (KR); Baek yu KIM, Hwaseong-si (KR); Chul Min AHN, Hwaseong-si (KR); Dong Hui CHEON, Hwaseong-si (KR); Sun Sung KWON, Hwaseong-si (KR); Won Seok LEE, Hwaseong-si (KR); Young Suk NAM, Hwaseong-si (KR); Sang Hyung HAN, Daejeon (KR); Seung Woo KIM, Daejeon (KR)

(73) Assignees: Hyundai Motor Company, Seoul (KR); Kia Corporation, Seoul (KR); KOREA ADVANCED INSTITUTE OF SCIENCE AND TECHNOLOGY, Daejeon (KR)

(21) Appl. No.: 19/388,777

(22) Filed: Nov. 13, 2025

(30) Foreign Application Priority Data
Apr. 11, 2025 (KR) 10-2025-0047645

(51) Int. Cl. H05K 7/20

(52) U.S. Cl. CPC H05K 7/20272; H05K 7/20436; H05K 7/20927

(57) ABSTRACT

A power module cooler includes a first housing, a first passage line disposed at one side inside the first housing and through which a first coolant flows for use in cooling a power module, a second passage line disposed at the other side inside the first housing and through which the first coolant flows, a plurality of jet holes disposed at the first and second passage lines, and configured to spray the first coolant onto a first surface of the power module, and a discharge line recessed inward between the first and second passage lines, and through which a second coolant flows for use in cooling the power module.

### CROSS-REFERENCE TO RELATED APPLICATION

The present application claims priority to Korean Patent Application No. 10-2025-0047645, filed on Apr.11, 2025, the entire contents of which are incorporated herein for all purposes by this reference.

### FIELD OF THE PRESENT DISCLOSURE

The present disclosure relates to a power module cooler.

### BACKGROUND

Recently, as power electronic systems become more high-powered and miniaturized, the heat generation of a power module that occurs in a power conversion device, such as an inverter, becomes an important issue. The power module generate a great amount of heat during high-power electrical switching, and when the heat is not properly managed, heat-induced problems may arise, such as performance degradation, shortened lifespan, and damage (breakage due to overheating). Specifically, there is a need to effectively cool a hot spot where heat is concentrated in the power module.

### BRIEF SUMMARY

According to various aspects of the present disclosure, the present disclosure aims to provide a cooler for effectively removing a hot spot by allowing a coolant to be intensively sprayed on a local area.

According to various aspects of the present disclosure, the present disclosure aims to provide a cooler for maximizing heat transfer performance by enlarging a heat transfer area and inducing turbulence formation with a Pin-Fin heat-exchange structure.

According to various aspects of the present disclosure, the present disclosure aims to provide a cooler that is configured to perform both local area cooling and overall area cooling by combining a jet-impingement cooling method with a channel cooling method.

According to various aspects of the present disclosure, the technical problems to be solved in the present disclosure are not limited to those mentioned above, and other technical problems not mentioned above shall be clearly understood by those skilled in the art in to which the present disclosure pertains from the description below.

According to various aspects of the present disclosure, there is disposed a power module cooler including a first housing, a first passage line in which a coolant flows, the first passage line disposed at a first side in the first housing and including a plurality of first jet holes to allow the coolant to be sprayed therethrough from the first passage line toward a first surface of the power module, a second passage line in which the coolant to flow, the second passage line disposed at a second side in the first housing and including a plurality of second jet holes to allow the coolant to be discharged therethrough from the second passage line toward the first surface of the power module, and a discharge line collecting and allowing the sprayed coolant to be discharged out of the first housing.

According to various aspects of the present disclosure, the discharge line may be disposed between the first passage line and the second passage line.

According to various aspects of the present disclosure, the plurality of first jet holes or the plurality of second jet holes may be configured to target by the sprayed coolant a local heat generation point on the first surface of the power module.

According to various aspects of the present disclosure, the local heat generation point may include an area where at least one semiconductor chip is placed in the power module.

According to various aspects of the present disclosure, the first housing may include a gasket groove in a part coupled to the power module to secure water tightness.

According to various aspects of the present disclosure, the power module may include an insulating substrate including a plurality of pin-fins.

According to various aspects of the present disclosure, the insulating substrate may include an insulating layer made of silicon nitride.

According to various aspects of the present disclosure, the cross-sectional shapes of the plurality of pin-fins may include a circle, a square, a triangle, a polygon, or any combination thereof.

According to various aspects of the present disclosure, the first housing may include a heat sink including a plurality of pin-fins.

According to various aspects of the present disclosure, the first housing may be attached by welding or bolts.

According to various aspects of the present disclosure, the power module may be attached to the heat sink by a thermal interface material.

According to various aspects of the present disclosure, the cooler may further include a second housing configured to cool a second surface of the power module.

According to various aspects of the present disclosure, the second housing may include a flow path formed as a channel to allow the coolant to flow therein.

According to various aspects of the present disclosure, the coolant may bifurcate and flow into the first housing and the second housing.

According to various aspects of the present disclosure, the coolant may flow into the first housing to pass therethrough and thus flow into the second housing.

According to various aspects of the present disclosure, the power module cooler may further include a third housing configured to cool a second surface of the power module, wherein the third housing includes the same structure as the first housing.

According to various aspects of the present disclosure, a coolant may be sprayed at high speed through a jet impingement cooler and cooled intensively at the hot spot of the power module, thereby effectively lowering the temperature of the area where heat is concentrated. Accordingly, performance degradation and the damage to the power module due to heat concentration may be prevented.

According to various aspects of the present disclosure, a coolant uniformly distributed over the entire area of the power module with an additional channel cooler may enable overall uniform cooling. Overall cooling may be improved along with local cooling, thereby resolving temperature imbalance and improving the stability and reliability of the power module.

According to various aspects of the present disclosure, the pin-fin structure on the surface of the cooler may maximize the heat transfer area with the coolant and induce turbulence near to the pin, thereby enhancing heat transfer performance. Therefore, a thermal boundary layer may become thinner to maximize cooling efficiency.

The effect that is obtained from the present disclosure is not limited to the above. The technical effect not mentioned above may be explicitly known to those skilled in the art from the description below.

### BRIEF DESCRIPTION OF DRAWINGS

FIG. 1 is a view exemplarily illustrating a power module cooler including a jet impingement cooler according to an exemplary embodiment of the present disclosure;

FIG. 2A and 2B are views exemplarily illustrating a direct cooling method and an indirect cooling method of a power module cooler according to an exemplary embodiment of the present disclosure;

FIG. 3 is a view exemplarily illustrating a power module cooler including a jet impingement cooler and a channel cooler according to an exemplary embodiment of the present disclosure;

FIG. 4A and 4B are views exemplarily illustrating the inflow and discharge of a coolant of a power module cooler according to an exemplary embodiment of the present disclosure;

FIG. 5A and 5B are views exemplarily illustrating a coolant flow method of a power module cooler according to an exemplary embodiment of the present disclosure;

FIG. 6A and 6B are views exemplarily illustrating a power module cooler including a cooler at the top portion of the power module according to an exemplary embodiment of the present disclosure; and

FIG. 7 is a view exemplarily illustrating the shape of a Pin-Fin structure according to an exemplary embodiment of the present disclosure.

### DETAILED DESCRIPTION

While embodiments are described with reference to the accompanying drawings, it should be understood that various changes and modifications may be made in the present disclosure. Furthermore, it should be understood that the present disclosure is not limited to the specific embodiments thereof, and various changes, equivalences, and substitutions may be made without departing from the scope and spirit of the present disclosure.

In the exemplary embodiments of the present disclosure, terms such as “module”, “unit”, “part”, and the like are terms used for nominal distinct between components, and it should not be interpreted as assuming that they are physically and chemically separated or capable of being separated or divided.

Terms containing ordinal numbers, such as “first”, “second”, etc., may be used to describe various components, but the components are not limited by the terms. These terms may be used only in a nominal sense to differentiate one component from another component, and their mutual sequential meaning will be understood through the context of the corresponding description, not through such terms.

The term “and/or” is used to include all instances of any combination of multiple items being the subject. For example, “A and/or B” includes all three cases: “A”, “B”, and “A and B”.

When a component is used to be "coupled" or "connected" to another component, it will be understood that the component may be either connected directly to another component, or connected indirectly via another medium.

The terms in the present application are used to describe an exemplary embodiment and do not intend to restrict and/or limit the present disclosure. Singular forms are intended to include plural forms unless the context clearly indicates otherwise. According to an exemplary embodiment of the present disclosure, terms such as “comprise” or “consist of” are used to designate presence of characteristics, numbers, steps, operations, elements, components or a combination thereof, and do not foreclose the presence or possibility of addition of one or more other characteristics, numbers, steps, operations, elements, components or a combination thereof.

Unless otherwise defined, all terms used in the exemplary embodiment of the present disclosure including technical or scientific terms, include the same meaning as generally understood by an ordinary person skilled in the technical field to which the present disclosure pertains. Terms defined in commonly used dictionaries will be interpreted as having a meaning consistent with the meaning in the context of the related technology, and unless clearly defined in the present application, should not be interpreted in an ideal or excessively formal sense.

An exemplary embodiment of the present disclosure will be explained with reference to the drawings.

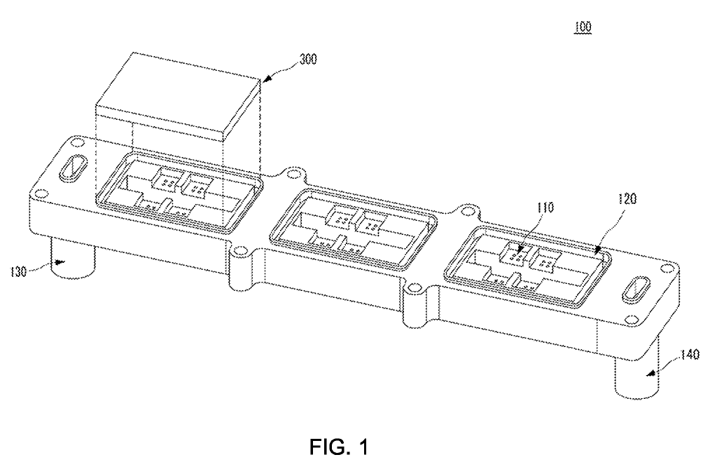

FIG. 1 is a view exemplarily illustrating a power module cooler including a jet impingement cooler according to an exemplary embodiment of the present disclosure.

Referring to FIG. 1, a power module cooler including a jet impingement cooler 100 according to an exemplary embodiment of the present disclosure may include a first housing 120. The first housing 120 may be the body of the jet impingement cooler 100, and may include a jet hole 110, a distribution chamber 125, a coolant inlet 130, a coolant outlet 140, and a gasket groove 150.

The first housing 120 of the jet impingement cooler 100 may be designed to spray the coolant 10 at high speed to perpendicularly impinge on the surface of a heat resource, thereby intensively removing heat in a local area. According to an exemplary embodiment of the present disclosure, the heat resource surface may be the bottom portion of a power module 300. The coolant 10 may include a first coolant to be used for cooling the power module, and a second coolant used for cooling the power module. The power module 300 may include one or more insulated gate bipolar transistors (IGBPs), one or more metal oxide semiconductor FETs (MOSFETs), or diodes, without being limited thereto.

The jet hole 110 may include a plurality of holes for spraying the coolant 10, which are placed at a predetermined distance on the surface of the first housing 120, and the hole of the jet hole 110 may be formed in various shapes, such as a circle, rectangle, ellipse, or slot. The diameter of the jet hole 110 may have an optimal size determined based on the pressure and flow rate of the coolant 10, and the length of the hole may be determined based on the diameter to stabilize the coolant flow and contribute to forming turbulence.

The jet hole 110 may be formed in a grid arrangement, diagonal arrangement, etc. to uniformly spray the coolant onto the surface of a cooling target. In the grid arrangement, the space between the grids may be formed to satisfy the spray range of the coolant 10 and the heat removal requirements of a local area, and the diagonal arrangement may be used in the case of more intensive cooling in a local heat concentration area (Hot Spot). Furthermore, more of the coolant 10 may be sprayed on a local area by adjusting the density of the jet hole 110 according to the heat generation characteristic of the cooling target.

The coolant 10 may maintain a constant pressure in the distribution chamber 125 to be supplied to the jet hole 110. The coolant 10 that passes through the jet hole 110 may be sprayed at high speed and may perpendicularly impinge on the surface of the cooling target, thereby maximizing heat transfer efficiency. The sprayed coolant 10 may impinge on the surface to form turbulence and render a thermal boundary layer thinner to increase a heat transfer speed. According to an exemplary embodiment of the present disclosure, the jet hole 110 may be formed under the power module 300 to allow the coolant 10 to perpendicularly impinge on the bottom portion of the power module 300.

The pressure and flow rate of the coolant 10 may be controlled so that the coolant 10 may be uniformly sprayed through the jet hole 110, and a flow rate control valve and a pressure sensor may be additionally included. The jet hole 110 may be designed to allow the coolant 10 to form a turbulence, which maximizes heat transfer performance, and the turbulence may accelerate to remove local heat and effectively remove the thermal boundary layer. The jet hole 110 may be manufactured from a material having durability against the flow rate and pressure of the coolant, and the material may be a corrosion-resistant material such as stainless steel, aluminum alloy, or copper.

The coolant inlet 130 may have various shapes depending on coolant flow characteristics and the requirements of a connecting device. In general, an inlet in a circular or oval shape may be used and the interior may be smoothly finished to minimize flow resistance. The diameter of the coolant inlet 130 may be formed to allow the coolant to maintain an appropriate flow rate and pressure, and the diameter may be adjusted according to the requirements of the cooler. The coolant inlet 130 may be connected to an external coolant supply device, and one of a threaded, flanged, or push-fit connection structure may be applied.

The interior of the coolant inlet 130 may be formed with a smooth finish to minimize the turbulence of the coolant 10 and stably maintain the flow. The coolant inlet 130 may uniformly distribute the pressure of the coolant 10 to maintain the flow balance before the coolant 10 is delivered to each jet hole 110.

To allow the coolant inlet 130 to transmit the pressure transmitted from a supply pump of the coolant 10 to the inside without loss, the size and shape of the coolant inlet 130 may be designed to prevent pressure drop and supply the coolant 10 to the jet hole 110 at a constant flow rate. Since the coolant inlet 130 operates in an environment where the coolant 10 flows in at a high pressure, the coolant inlet 130 may be made from a highly durable material including one of stainless steel, aluminum alloy, copper alloy, or polymer material with excellent corrosion resistance. To prevent leakage of the coolant 10, the connecting part between the coolant inlet 130 and the distribution chamber 125 may use a sealing material such as a gasket or an O-ring.

The coolant outlet 140 may be designed to effectively discharge the coolant 10 and may generally have a circular or oval shape. The size and shape of the coolant outlet 140 may be determined depending on the flow rate and pressure of the coolant 10, and device design requirements. The size of the coolant outlet 140 may be adjusted according to the design flow rate of the cooler for smooth discharging of the coolant 10. The coolant outlet 140 may have a discharging direction to allow the coolant 10 to be discharged to the outside with minimal turbulence inside the cooler. The coolant outlet 140 may be disposed at the side or under the cooler, so that the discharged coolant may naturally flow out to the outside of the device.

The coolant outlet 140 may include an interior with a smooth finish to minimize the pressure loss that may occur during the discharging of the coolant 10, and may reduce the flow resistance of the coolant. For smooth discharging of the coolant 10, the outlet may be designed in consideration of fluid dynamic characteristics of the device. The coolant outlet 140 may include an optimal internal structure to minimize the turbulence during the discharging of the coolant and maintain a constant flow. A deflector or a guide may be added to control the coolant flow as needed. The coolant outlet 140 may be made from a highly corrosion-resistant material such as stainless steel, aluminum alloy, or polymer material not to corrode even when the coolant 10 flows for a long time. The coolant outlet 140 may have structural strength to ensure stable operation even in a high-pressure and high-temperature environment, and the connecting part between the coolant outlet 140 and the distribution chamber 125 may include a sealing structure such as an O-ring or a gasket to prevent coolant leakage.

The coolant 10 may impinge on the surface of the cooling target through the jet hole 110 and absorb heat. The coolant 10 that completes heat-exchange may flow into the coolant outlet 140 and flow out to the outside of the device. The coolant outlet 140 may provide a stable discharge path to allow the coolant 10 to uniformly flow and prevent cooling efficiency degradation due to a residual coolant.

The coolant outlet 140 may minimize the flow resistance that may occur during the discharging of the coolant 10 and maintain the heat transfer performance of the cooler. The design of the coolant outlet 140 may reduce the pressure loss in the discharge path of the coolant 10 and reduce the load of a coolant circulation pump. The long-term reliability of the device may be ensured through the stable discharge of the coolant 10, and the residual coolant may be promptly removed through the coolant outlet 140, thereby preventing the coolant that stays inside the cooler.

The gasket groove 150 may be formed to properly position a gasket 320 and distribute pressure load uniformly. Generally, the gasket groove 150 may include a square, oval, or V-shaped cross-section, and may be optimized depending on the material and shape of the gasket 320. The depth of the gasket groove 150 may be designed in consideration of the thickness of the gasket 320 and the contact pressure between the cooler and the power module 300. Generally, the groove may have a depth ranging from approximately 50~80% of the thickness of the gasket 320, and the width may be set to allow the deformation of the gasket 320 while maintain its sealing properties. The gasket groove 150 may be formed on the surface where the first housing 120 contacts with the power module 300, and disposed along the periphery of the flow path of the coolant 10.

In the gasket groove 150, the gasket 320 may be stably fixed to prevent the leakage of the coolant and maintain the sealing properties of the device. The mechanical stress of the bonding part may be reduced by uniformly distributing the pressure between the first housing 120 and the power module 300. The gasket groove 150 may maintain the sealing state of the gasket 320 from vibrations or impacts.

The gasket groove 150 may be formed of a material identical to or similar to that of the first housing 120, and generally the material may be aluminum alloy, stainless steel, or high-strength plastic. The surface of the gasket groove 140 may be made with a smooth finish to prevent damage to the gasket 320 and increase adhesion. The gasket groove 150 may provide the space to be properly deformed when the gasket 320 receives load, thereby maximizing sealing performance. The gasket 320 may be designed within an allowance range not to be damaged by being over-pressed. The gasket groove 150 may be formed of a durable material not to be corroded even by continuous contact with the coolant 10, and may be coated to provide excellent waterproofing and corrosion resistance. The gasket groove 150 may include a structure into which the gasket 320 is easily inserted and stably fixed, thereby simplifying an assembly process.

The gasket 320 may be inserted into the gasket groove 150 during an assembly process. When the first housing 120 and the power module 300 are assembled, the gasket 320 may be compressed and fixed inside the groove. The gasket 320 may maintain the sealing state at the periphery of the inlet and outlet of the coolant, and the internal flow path, thereby preventing the leakage of the coolant.

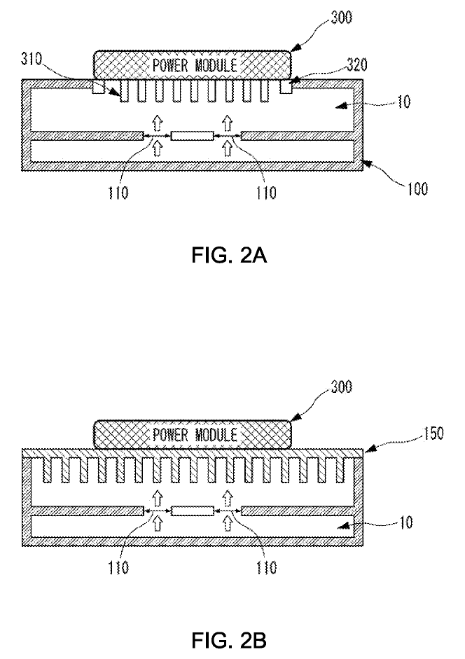

FIG. 2A and 2B are views exemplarily illustrating a direct cooling method and an indirect cooling method of a power module cooler according to an exemplary embodiment of the present disclosure.

Referring to FIG. 2A and 2B, a power module cooler according to an exemplary embodiment of the present disclosure may include a jet impingement cooler 100, and one of the direct cooling method and the indirect cooling method may be applied to the jet impingement cooler 100.

Referring to FIG. 2A, the direct cooling method may be applied to the jet impingement cooler 100 according to an exemplary embodiment of the present disclosure.

In the direct cooling method applied to the jet impingement cooler 100 according to an exemplary embodiment of the present disclosure, the coolant 10 may directly contact with the surface of an insulating substrate of the power module 300 to remove heat.

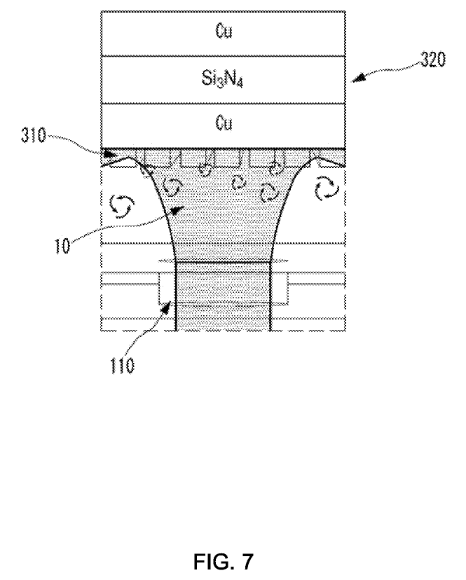

According to the direct cooling method, the coolant 10 sprayed from the jet hole 110 may be directly sprayed onto the surface through a Pin-Fin structure 310 (refer to FIG. 7), and the insulating substrate to which the pin-fin structure is applied may directly contact with the coolant, thereby shortening the heat transfer path.

The leakage of the coolant 10 may be prevented by use of the gasket 320, and the sealing between the first housing 120 and the power module 300 may be maintained. A sealer method may be applied in addition to a gasket method to prevent the leakage of the coolant 10.

Referring to FIG. 2B, the indirect cooling method may be applied to the jet impingement cooler 100 according to an exemplary embodiment of the present disclosure.

In the indirect cooling method applied to the jet impingement cooler 100 according to an exemplary embodiment of the present disclosure, the coolant 10 may remove the heat of the power module 300 indirectly through a heat sink 160.

According to the indirect cooling method, the heat sink 160 may be disposed at the bottom portion of the power module 300 to absorb heat first, and may transfer the heat to the coolant 10 sprayed from the jet hole 110 through a pin-fin structure 161 of the heat sink. The coolant 10 may not directly contact with the power module 300. The sealing between the heat sink 160 and the first housing 120 may be maintained by welding or bolt coupling.

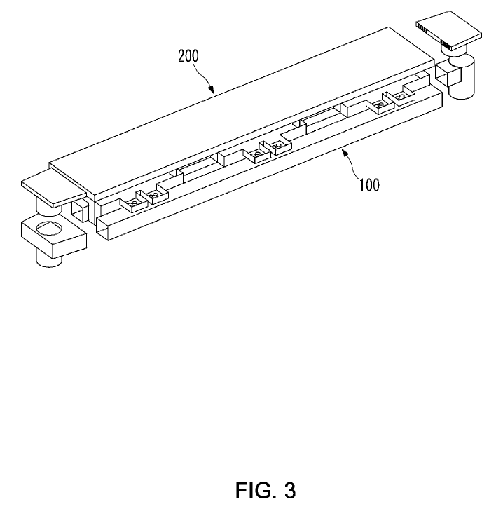

FIG. 3 is a view exemplarily illustrating a power module cooler including a jet impingement cooler and a channel cooler according to an exemplary embodiment of the present disclosure.

Referring to FIG. 3, a power module cooler may include a jet impingement cooler 100 and a channel cooler 200.

The jet impingement cooler 100 is described with reference to FIG. 1, and the description of the channel cooler will be detailed below.

The channel cooler 200 may include a second housing 220. The second housing 220 may be the body of the channel cooler 200, and may include a channel 210, a channel cooler coolant inlet 230, and a channel cooler coolant outlet 240.

The second housing 220 may include a structure where the coolant 10 flows along a plurality of channels 210 to uniformly remove the heat of the cooling target. The second housing 220 may provide a large cooling surface area and a uniform heat distribution performance, which maximizes cooling efficiency.

The second housing 220 may include a plurality of channels 210 that form the flow path of the coolant 10 and each of the channels may be in close contact with the top portion of the power module 300 to enable heat transfer. The plurality of channels 210 may be disposed at a predetermined distance, so that the coolant 10 may be uniformly distributed.

The coolant 10 may flow into the second housing 220 through the channel cooler coolant inlet 230, and pass through the channel 210 to be discharged through the channel cooler coolant outlet 240. The channel cooler coolant inlet 230 and the channel cooler coolant outlet 240 may stabilize the coolant flow inside the channel 210 and minimize pressure loss.

The cross-section of the channel 210 may be rectangular, circular, or semi-circular, and optimized according to the flow characteristic and heat transfer performance of the coolant 10. The size of the cross-section of the channel 210 may be adjusted in consideration of the flow rate and pressure of the coolant.

The second housing 220 may be made of a material with high thermal conductivity such as aluminum alloy, copper, or stainless steel. The surface of the cooler may be coated to ensure corrosion resistance and wear resistance.

The density of the channel 210 of the second housing 220 may be adjusted depending on the heat generation characteristic of the power module 300 and the required cooling performance. The coolant may be intensively supplied in a high-heat area with the increased channel density, and the density may be lower in a low-heat area to maintain balance.

The coolant flow inside the channel 210 of the second housing 220 may maximize the heat transfer efficiency by inducing turbulence. The channel may include a structure such as a rib or a deflector to ensure the stability of the coolant flow inside the channel 210.

The surface inside the channel of the second housing 220 may be made with a smooth finish to reduce the pressure loss that may occur when the coolant 10 passes through the channel 210. The design of the coolant inlet 230 and the coolant outlet 240 of the second housing 220 may be optimized to minimize the pressure loss.

The coolant flowing into the second housing 220 may be uniformly distributed. A flow valve that controls the pressure difference between the channel cooler coolant inlet 230 and the channel cooler coolant outlet 240 may be used.

The coolant 10 may be uniformly distributed over a large area through the channel 210, and the second housing 220 may prevent a hot spot of the cooling target and remove heat uniformly. by use of a material with a high turbulence formation and heat conductivity inside the channel 10, the high heat transfer performance may be provided. Optimization of the size, shape, and internal structure of the channel 210 may reduce the flow resistance of the cooler 10 and increase the efficiency of a device.

The second housing 220 may optimize the size and number of channels according to the flow rate and pressure to increase the cooling efficiency. In consideration of the heat generation characteristic of the power module 300, the channel density and distribution may be designed, and the appropriate material may be used in consideration of thermal conductivity, corrosion resistance, and durability.

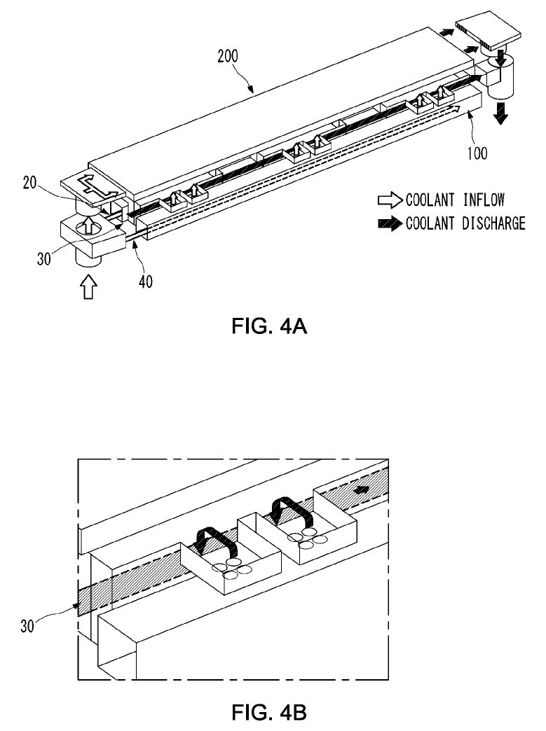

FIG. 4A and 4B are views exemplarily illustrating inflow and outflow of the coolant of a power module cooler according to an exemplary embodiment of the present disclosure.

Referring to FIG. 4A and 4B, the power module cooler according to an exemplary embodiment of the present disclosure may include the jet impingement cooler 100 and the channel cooler 200.

Referring to FIG. 4A, the jet impingement cooler 100 may include a first passage line 20, a second passage line 40, and a discharge line 30.

The coolant 10 flowing into the coolant inlet 130 may be distributed to the jet hole 110 through the first passage line 20 and the second passage line 40. The coolant 10 that passes through the jet hole 110 may be perpendicularly sprayed onto the lower portion of the power module 300, and the coolant may be collected in the discharge line 30. The first passage line 20 and the second passage line 40 may be passages where the coolant flows along to the jet hole 110, and the discharge line 30 may be a passage where the cooled coolant is discharged. The jet hole 110 may be disposed on the top portion of the first passage line 20 and the second passage line 40.

FIG. 4B is an enlarged view exemplarily illustrating the discharge line 30.

After the coolant 10 that passes through the jet hole 110 is perpendicularly sprayed onto the bottom portion of the power module 300, the coolant may be collected in the discharge line 30, and the coolant may be discharged to the coolant outlet 140.

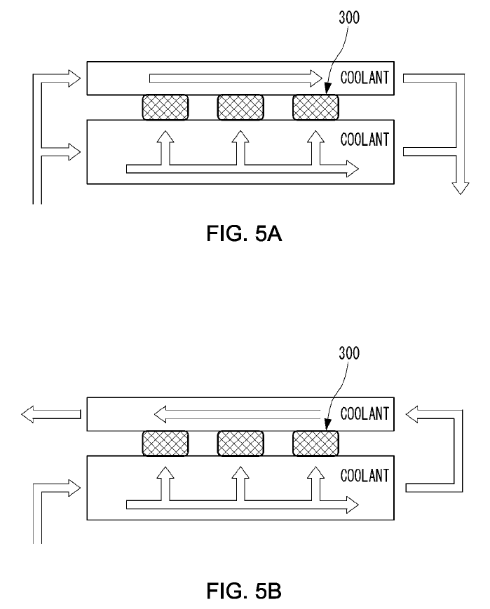

FIG. 5A and 5B are views exemplarily illustrating a coolant flow method of a power module cooler according to an exemplary embodiment of the present disclosure.

Referring to FIG. 5A and 5B, a power module cooler according to an exemplary embodiment of the present disclosure may include a cooler disposed at the top portion and bottom portion of the power module 300.

The jet impingement cooler 100 may be disposed at the bottom portion of the power module 300, and the power module cooler including the jet impingement cooler 100 or the channel cooler 200 may be disposed at the top portion of the power module 300, and thus at least one of parallel and series coolant flow methods may be used.

FIG. 5A illustrates includes a parallel cooling method of a power module cooler according to an exemplary embodiment of the present disclosure.

According to the parallel cooling method, the coolant 10 may branch off into multiple paths at the inlet, and pass through each cooler individually and rejoin to be discharged through the outlet.

In the parallel cooling method, the coolant 10 may branch off into multiple paths at the outlet, and the coolant 10 may be distributed to each cooler simultaneously. Multiple coolers may have dependent paths and contact with the coolant in parallel, and the coolant that passes through each cooler may rejoin to be discharged through the outlet.

According to the parallel cooling method, the coolant 10 may be distributed into multiple paths to balance a flow rate, thereby minimizing pressure loss in each individual path. When the same flow rate and pressure are supplied in respective coolers connected in parallel, uniform cooling performance may be ensured, and the entire flow rate may be distributed in parallel, thereby removing heat promptly.

According to the parallel cooling method, pump load may be small because the pressure loss is small, and the performance of individual cooler may be stable and uniform. Therefore, the high-heat areas may be separated and managed by an individual cooler. However, the parallel cooling may have a complicated design and manufacturing process and require an equal flow rate for each cooler. When a flow imbalance occurs in a distribution device, the performance of some coolers may be degraded.

FIG. 5B illustrates a series cooling method of a cooling flow method of a power module cooler according to an exemplary embodiment of the present disclosure.

According to the series cooling method, the coolant 10 may pass through a single cooler at the inlet and continually flows to a next cooler.

According to the series cooling method, the coolant 10 may flow into a cooler through a single path. The coolant 10 may pass through the first cooler and continuously move to a next cooler to remove heat. The coolant 10 that passes through the last cooler may be discharged through the outlet.

According to the series cooling method, the coolant 10 may pass through a single path, so that the design and the manufacturing process may be simple. However, since the coolant 10 may absorb heat already while passing through the first cooler, the performance of the cooler may be reduced. While the coolant 10 continuously passes through multiple coolers, the passage may become longer, and the pressure loss may increase.

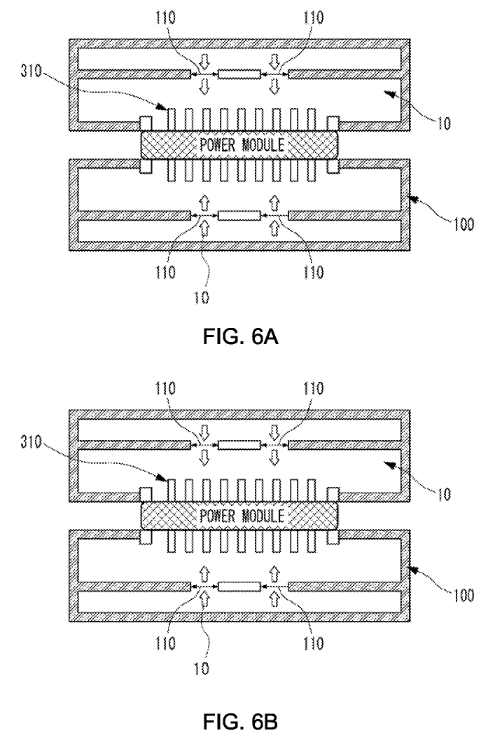

FIG. 6A and 6B are views exemplarily illustrating a power module cooler including a cooler at the top portion of the power module according to an exemplary embodiment of the present disclosure.

Referring to FIG. 6A and 6B, a power module cooler according to an exemplary embodiment of the present disclosure may include a cooler at the top portion of the power module 300.

Referring to FIG. 6A, the jet impingement cooler 100 may be disposed at the bottom portion of the power module 300, and the channel cooler 200 may be disposed at the top portion of the power module 300. The configuration above may be the same as that shown in FIGS. 3 and 4A and 4B. Referring to FIG. 6B, according to another exemplary embodiment of the present disclosure, the jet impingement cooler 100 and not the channel 200, may be disposed at the top portion of the power module 300.

FIG. 7 is a view exemplarily illustrating the shape of a pin-fin structure according to an exemplary embodiment of the present disclosure.

Referring to FIG. 7, a heat-exchange portion in a pin-fin shape 310 may be placed under an insulating substrate of the power module 300.

The heat-exchange portion in the pin-fin shape 310 may be directly disposed under the insulating substrate of the power module 300, and may be formed in various shapes such as a cylindrical pin, a polygonal pin, etc. The cylindrical pin shape may have a high heat transfer performance and easy manufacturing process, and the polygonal pin shape may have a large heat transfer area to enhance the efficiency.

The pin-fin shape 310 may be a structure that protrudes in a pin shape to improve the heat transfer performance on the insulating plate under the power module 300. The pin-fin shape 310 may increase the heat transfer efficiency by maximizing the contact area with the coolant 10 and render a thermal boundary layer to be thin by inducing turbulence near to the pin.

An insulating layer 330 of the insulating substrate of the power module 300 may be made of silicon nitride (Si3N4). Silicon nitride (Si3N4) has excellent thermal conductivity, durability, electrical insulation, corrosion resistance, etc. compared to existing ceramics, which is suitable for high-power electronic devices (e.g., electric vehicle inverters) and coolers that operate in extreme environments, thereby effectively solving heat generation problems.

Although exemplary embodiments have been shown and described, it will be appreciated by those skilled in the art that changes may be made to these exemplary embodiments without departing from the principles and spirit of the present disclosure. Accordingly, the scope of the present disclosure is not construed as being limited to the described exemplary embodiments of the present disclosure, but is defined by the appended claims as well as equivalents thereto.

Although exemplary embodiments have been shown and described, it will be appreciated by those skilled in the art that changes may be made to these exemplary embodiments without departing from the principles and spirit of the present disclosure.

Accordingly, the scope of the present disclosure is not construed as being limited to the described exemplary embodiments of the present disclosure, but is defined by the appended claims as well as equivalents thereto.

What is claimed is:

1. A cooler for cooling a power module, the cooler comprising:
a first housing;
a first passage line in which a coolant flows, the first passage line disposed at a first side in the first housing and including a plurality of first jet holes, wherein the coolant is sprayed through the plurality of first jet holes from the first passage line toward a first surface of the power module;
a second passage line in which the coolant to flow, the second passage line disposed at a second side in the first housing and including a plurality of second jet holes, wherein the coolant is discharged through the plurality of second jet holes from the second passage line toward the first surface of the power module; and
a discharge line collecting and allowing the sprayed coolant to be discharged out of the first housing.

2. The cooler of claim 1, wherein the discharge line is disposed between the first passage line and the second passage line.

3. The cooler of claim 1, wherein the plurality of first jet holes or the plurality of second jet holes are configured to target by the sprayed coolant a local heat generation point on the first surface of the power module.

4. The cooler of claim 1, wherein the local heat generation point includes an area where at least one semiconductor chip is placed in the power module.

5. The cooler of claim 1, wherein the first housing includes a gasket groove in a portion coupled to the power module to secure water tightness.

6. The cooler of claim 1, wherein the first housing includes a distribution chamber, inside of which the plurality of first jet holes are disposed.

7. The cooler of claim 1, wherein the power module comprises an insulating substrate including a plurality of pin-fins.

8. The cooler of claim 7, wherein the insulating substrate includes an insulating layer made of silicon nitride.

9. The cooler of claim 7, wherein cross-sectional shapes of the plurality of pin-fins includes a circle, a square, a triangle, a polygon, or any combination thereof.

10. The cooler of claim 1, wherein the first housing comprises a heat sink including a plurality of pin-fins.

11. The cooler of claim 10, wherein the heat sink is attached by welding or bolts.

12. The cooler of claim 10, wherein the power module is attached to the heat sink by a thermal interface material.

13. The cooler of claim 1, further comprising:
a second housing configured to cool a second surface of the power module.

14. The cooler of claim 13, wherein the second housing comprises a flow path formed as a channel to allow the coolant to flow therein.

15. The cooler of claim 13, wherein the coolant bifurcates and flows into the first housing and the second housing.

16. The cooler of claim 13, wherein the coolant flows into the first housing to pass therethrough and thus flow into the second housing.

17. The cooler of claim 1, further comprising:
another first housing configured to cool a second surface of the power module.
